(19) United States
(12) Patent Application Publication
(10) Pub. No.: US 2026/0354221 A1
(43) Pub. Date: Nov. 5, 2026

(54) PACKAGE STRUCTURE AND FABRICATION METHOD THEREOF

(71) Applicant: Taiwan Semiconductor Manufacturing Company, Ltd., Hsinchu (TW)

(72) Inventors: Po-Ching Wu, Hsinchu (TW); Li-Han Hsu, Hsin-Chu City (TW); An-Jhih Su, Taoyuan City (TW); Der-Chyang Yeh, Hsin-Chu (TW)

(73) Assignee: Taiwan Semiconductor Manufacturing Company, Ltd., Hsinchu (TW)

(21) Appl. No.: 19/198,113

(22) Filed: May 4, 2025

(51) Int. Cl. H10W 70/60; H10W 70/40; H10W 70/63; H10W 70/692; H10W 90/00

(52) U.S. Cl. CPC H10W 70/611; H10W 70/465; H10W 70/635; H10W 70/692; H10W 90/401

(57) ABSTRACT

A package structure includes a substrate, an interposer, a glass layer, through glass vias (TGVs), and a semiconductor device. The interposer is disposed over the substrate. The glass layer is disposed between the substrate and the interposer. The TGVs are embedded in the glass layer and electrically connected to the substrate and the interposer. The semiconductor device is disposed over and electrically connected to the interposer.

### BACKGROUND

Semiconductor devices are evolving toward lighter, thinner, shorter, and more compact designs. As semiconductor technology advances, further miniaturization of various conductive features within these devices has become increasingly challenging. To enhance the integration density of semiconductor devices, advanced packaging technologies have been adopted. By optimizing packaging structures and interconnect designs, these techniques enable higher performance, improved space utilization, and enhanced electrical characteristics, addressing the limitations of traditional scaling approaches.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1K are schematic cross-sectional views showing various stages of a fabrication method for a package structure according to some embodiments of the present disclosure.

FIG. 2 is a schematic cross-sectional view showing a package structure according to some embodiments of the present disclosure.

FIGS. 3A to 3D are schematic cross-sectional views showing various stages of a fabrication method for a package structure according to some embodiments of the present disclosure.

FIGS. 4A to 4B are schematic cross-sectional views showing various stages of a fabrication method for a package structure according to some embodiments of the present disclosure.

FIG. 5 is a schematic cross-sectional view showing a package structure according to some embodiments of the present disclosure.

FIGS. 6A to 6D are schematic cross-sectional views showing various stages of a fabrication method for a package structure according to some embodiments of the present disclosure.

FIG. 7 is a schematic cross-sectional view showing a package structure according to some embodiments of the present disclosure.

FIG. 8 is a schematic cross-sectional view showing a package structure according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, a package structure consists of various materials, including semiconductor materials, metal materials, inorganic insulating materials, and organic insulating materials. Since these materials have different coefficients of thermal expansion (CTEs), the components within the package structure exhibit varying thermal expansion properties. As a result, thermal stress generated during the fabrication process may lead to structural issues such as warpage.

In a chip-on-wafer-on-substrate (CoWoS) package structure, semiconductor dies are bonded to an interposer, which is further bonded to a substrate, with the interposer positioned between the semiconductor dies and the substrate. In some embodiments of the present disclosure, a glass layer is introduced between the interposer and the substrate as a buffer structure, effectively alleviating issues related to warpage.

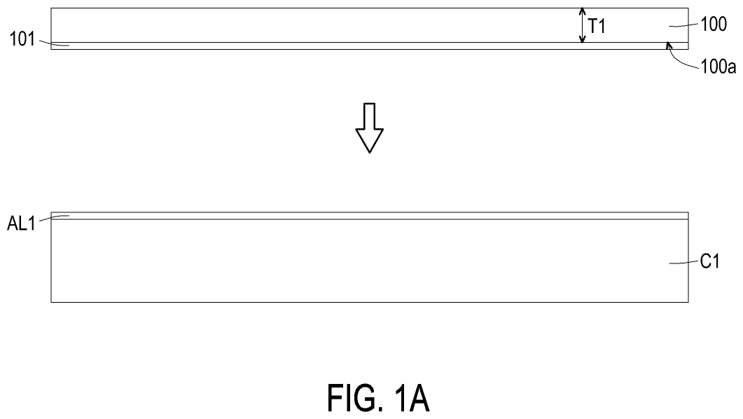

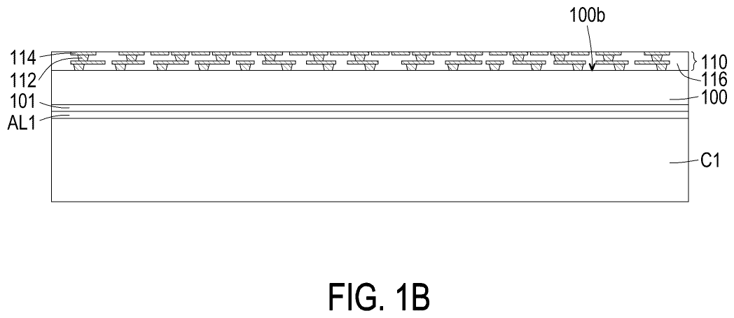

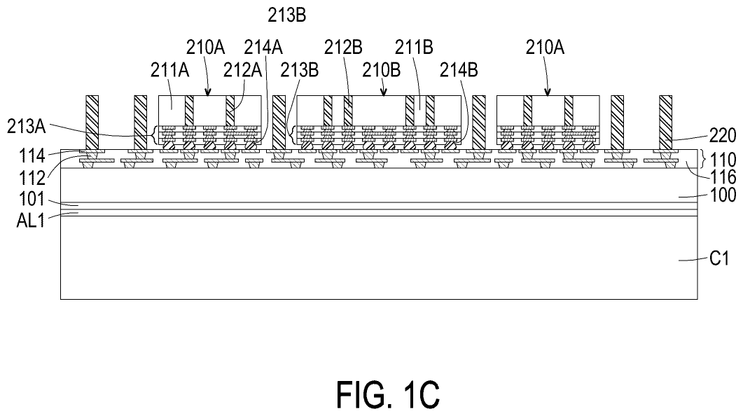

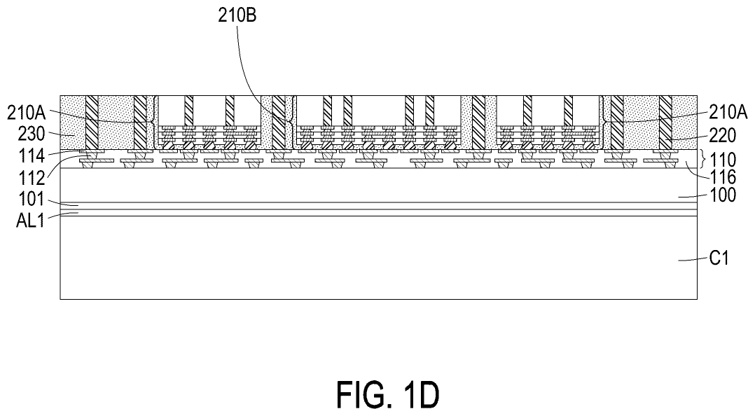

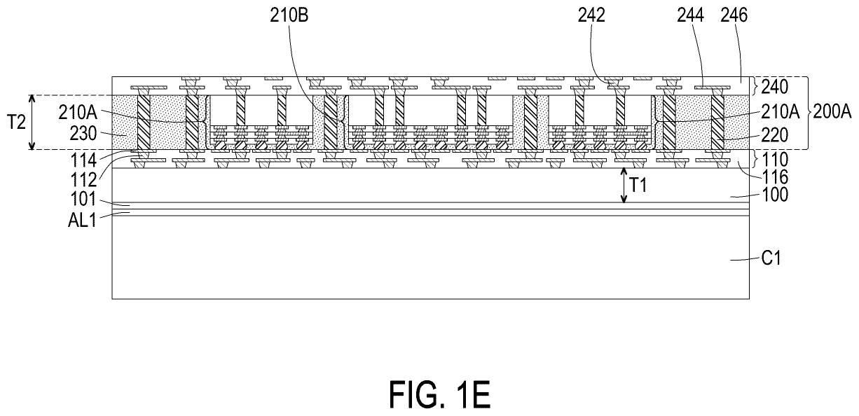

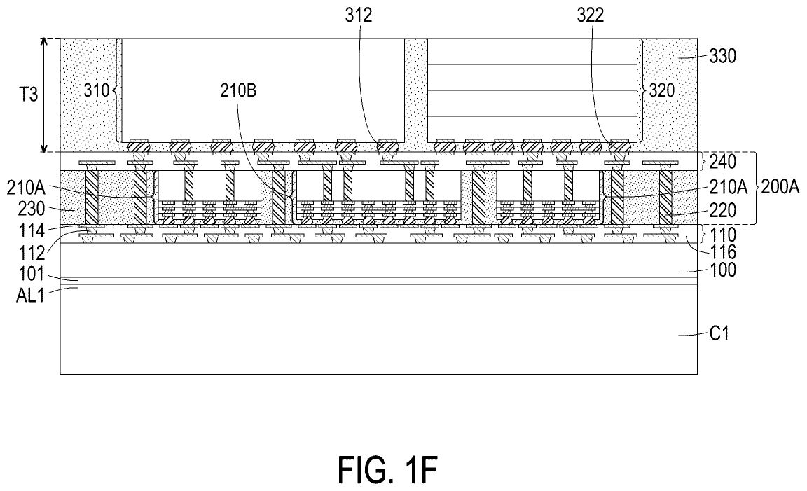

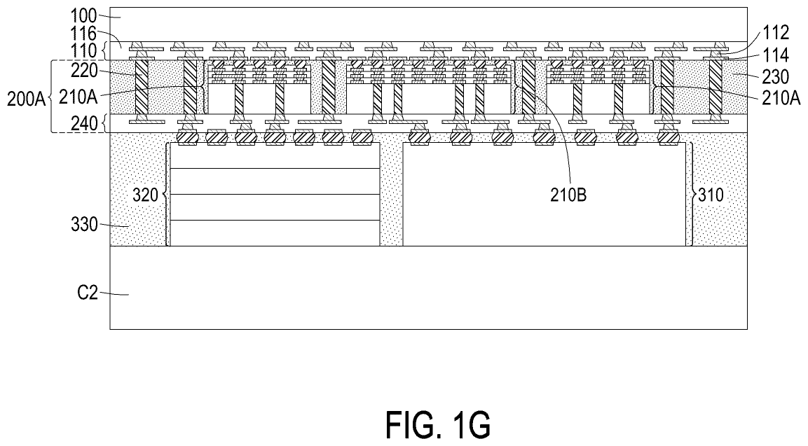

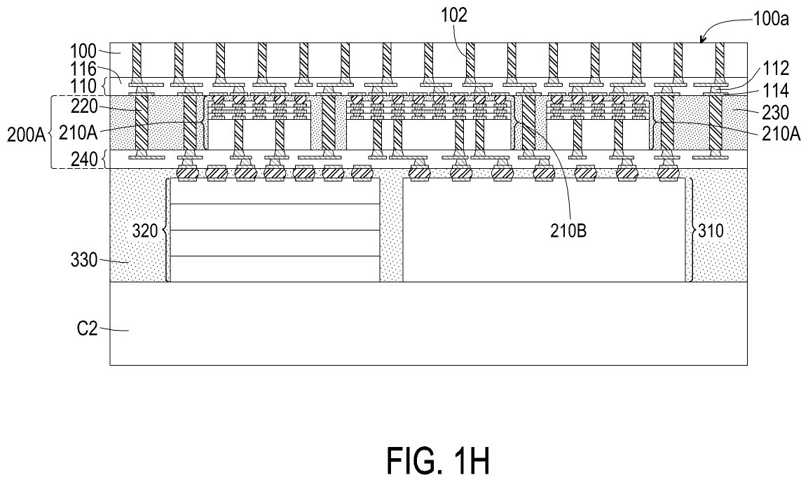

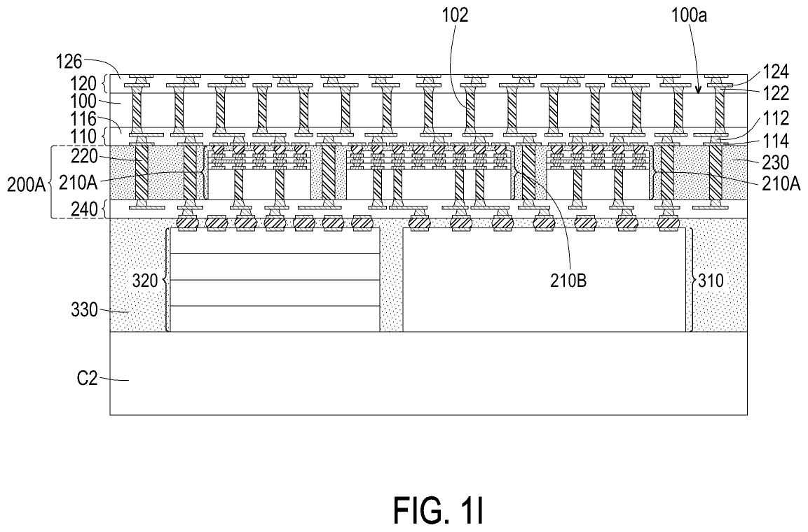

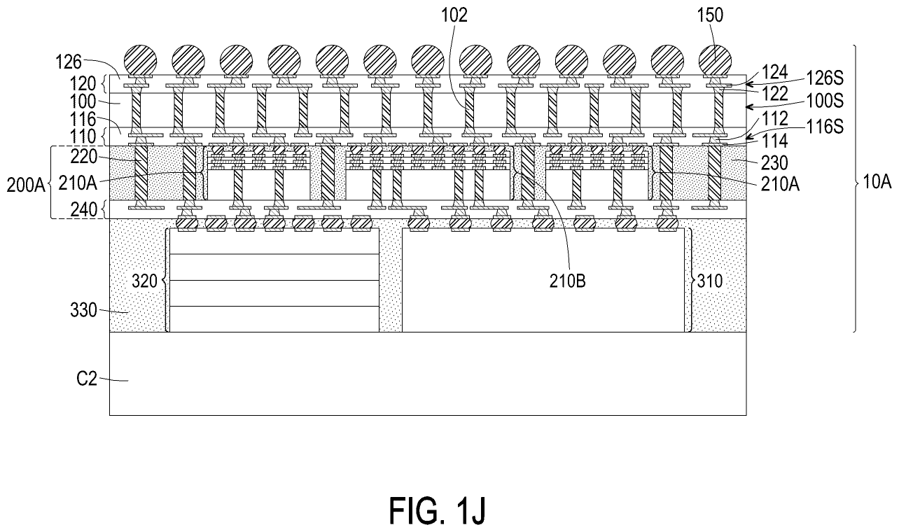

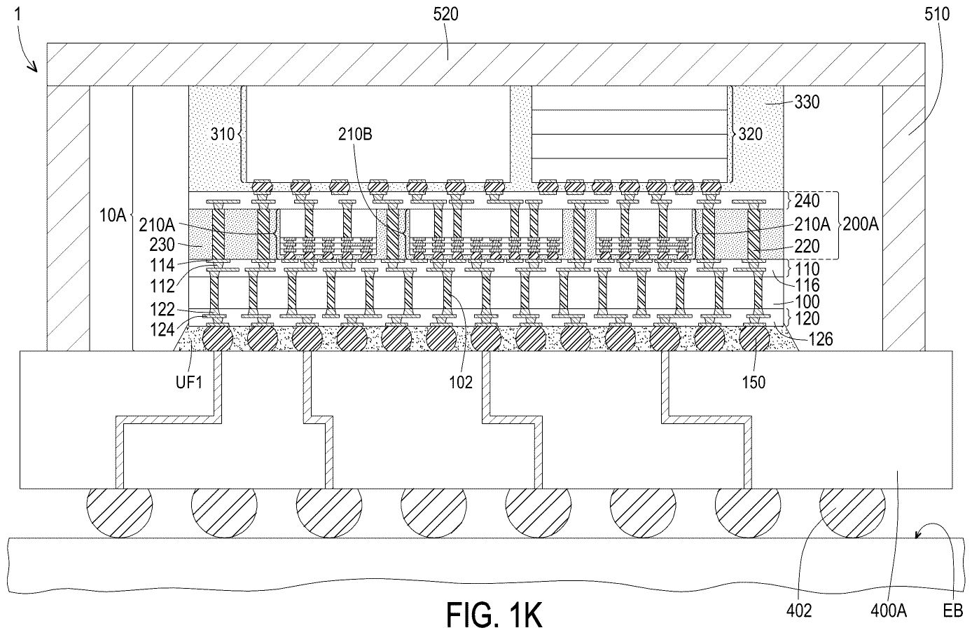

FIGS. 1A to 1K are schematic cross-sectional views showing various stages of a fabrication method for a package structure 1 according to some embodiments of the present disclosure. Referring to FIG. 1A, a glass layer 100 is bonded onto a first carrier C1. In some embodiments, the thickness T1 of the glass layer 100 is in a range from 0.1 mm to 1 mm. For example, the thickness T1 may be 0.2 mm, 0.3 mm, 0.4 mm, 0.5 mm, 0.6 mm, 0.7 mm, 0.8 mm, or 0.9 mm. However, the thickness T1 is not limited to these values, and the glass layer 100 may have other thicknesses.

In certain embodiments, a bulk glass is ground down until it reaches the desired thickness T1, forming the glass layer 100. A release film 101 is then applied to a first surface 100a of the glass layer 100. Subsequently, the glass layer 100 is bonded to the first carrier C1 via an adhesive layer AL1 formed on the first carrier C1. The first surface 100a of the glass layer 100 is facing to the first carrier C1.

In some embodiments, the glass layer 100 includes at least one of the following components: SiO₂, Al₂O₃, B₂O₃, MgO, CaO, BaO, Na₂O, K₂O, and the like. In certain embodiments, the glass layer 100 comprises doped silica glass. For example, the glass layer 100 may be made of a glass material doped with at least one of sodium oxide (Na₂O) and potassium oxide (K₂O). Increasing the content of sodium oxide and/or potassium oxide can enhance the coefficient of thermal expansion (CTE) of the glass layer 100. In other words, the CTE of the glass layer 100 can be adjusted as needed to meet specific requirements.

In some embodiments, the CTE of the glass layer 100 is in a range from 3 to 12 ppm/°C, such as 4 ppm/°C, 5 ppm/°C, 6 ppm/°C, 7 ppm/°C, 8 ppm/°C, 9 ppm/°C, 10 ppm/°C, or 11 ppm/°C. In certain embodiments, the CTE falls within a narrower range of 6 to 11 ppm/°C. Additionally, in some embodiments, the Young's modulus of the glass layer 100 is greater than 70 GPa, for example, within a range of 70 GPa to 100 GPa.

In some embodiments, the release film 101 may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the release film 101 may include a thermally decomposing adhesive material. For example, the release film 101 may include an acrylic pressure-sensitive adhesive that decomposes at an elevated temperature.

In some embodiments, the adhesive layer AL1 may include a die attach film (DAF) or other materials having adhesion property.

In some embodiments, the first carrier C1 may be a glass substrate, a sapphire substrate, or another suitable carrier. The thickness of the first carrier C1 is greater than the thickness T1 of the glass layer 100, and it serves to support the workpiece in the fabrication process.

Referring to FIG. 1B, a first redistribution layer (RDL) structure 110 is formed on the glass layer 100. Specifically, the first RDL structure 110 is formed over the second surface 100b of the glass layer 100. In some embodiments, the first RDL structure 110 comprises a dielectric structure 116, one or more redistribution layers (RDLs) 114, and vias 112. The dielectric structure 116 may include one or more dielectric layers, which may be made from materials such as silicon oxide, silicon nitride, silicon oxynitride, silicon carbide, or combinations thereof. Although two RDLs 114 are illustrated, the first RDL structure 110 may include more than two layers of RDLs 114. The RDLs 114 and the vias 112 may be formed using single- and/or dual-damascene processes, which involve etching the dielectric layers to form via openings and trenches, depositing a conductive barrier layer into the openings, plating a metallic material such as copper or a copper alloy, and performing planarization to remove excess metallic material. Additionally, etch stop layers may be present within the dielectric structure 116, though they are not explicitly shown in the figure.

Referring to FIG. 1C, at least one through insulating via (TIV) 220 is formed on the first RDL structure 110. In some embodiment, the TIVs 220 may be formed by forming a mask pattern having openings (not shown), where the mask pattern covers a portion of the first RDL structure 110 and exposes another portion of the first RDL structure 110 with the openings; forming a metallic material filling the openings to form the TIVs 220 by electroplating or deposition; and then removing the mask pattern. The material of the mask pattern may include a positive photo-resist or a negative photo-resist. However, the disclosure is not limited thereto.

In an alternative embodiment, the TIVs 220 may be formed by forming a seed layer (not shown) on the first RDL structure 110; forming the mask pattern with openings exposing portions of the seed layer; forming the metallic material on the exposed portions of the seed layer to form the TIVs 220 by plating; removing the mask pattern; and then removing portions of the seed layer exposed by the TIVs 220. For example, the seed layer may be a titanium/copper composited layer. For simplification, only six TIVs 220 are presented in FIG. 1C for illustrative purposes. However, it should be noted that less or more than six TIVs 220 may be formed; the disclosure is not limited thereto. The number of the TIVs can be selected based on the demand.

The interconnect dies 210A and 210B are placed on the first RDL structure 110. For example, the interconnect dies 210A and 210B are first positioned onto the first RDL structure 110 through a pick-and-place process. Subsequently, the interconnect dies 210A and 210B are bonded to the first RDL structure 110 through a bonding process. In some embodiments, each interconnect die 210A includes a semiconductor substrate 211A and an interconnect structure 213A disposed on the semiconductor substrate 211A. Similarly, the interconnect die 210B includes a semiconductor substrate 211B and an interconnect structure 213B disposed on the semiconductor substrate 211B. The interconnect dies 210A, 210B may have the same or different structures. In some embodiments, the interconnect dies 210A, 210B are local silicon interconnects (LSI).

The interconnect structures 213A and 213B each include an insulating structure with multiple conductive layers (also referred to as interconnect layers) and conductive vias embedded within. The number of conductive layers and conductive vias in the interconnect structures 213A and 213B can be adjusted according to actual requirements.

In this embodiment, the interconnect structure 213A disposed on the semiconductor substrate 211A is electrically connected to the first RDL structure 110 through conductive bumps 214A. Similarly, the interconnect structure 213B disposed on the semiconductor substrate 211B is electrically connected to the first RDL structure 110 through conductive bumps 214B. In this embodiment, the interconnect structures 213A and 213B are positioned on the side of interconnect dies 210A and 210B facing the first RDL structure 110. However, this disclosure is not limited thereto. In other embodiments, the interconnect structure may be located on the side of the interconnect die opposite to the first RDL structure 110, and the interconnect die may be bonded to the first RDL structure 110 through an adhesive layer (e.g., DAF), hybrid bonding, or the like.

In some embodiments, the interconnect die 210A optionally includes at least one through-semiconductor via (TSV) 212A. The TSVs 212A are embedded in the semiconductor substrate 211A and are electrically connected to the first RDL structure 110 through the interconnect structure 213A and conductive bumps 214A.

Similarly, the interconnect die 210B optionally includes at least one TSV 212B. The TSVs 212B are embedded in the semiconductor substrate 211B and are electrically connected to the first RDL structure 110 through the interconnect structure 213B and conductive bumps 214B.

In this embodiment, the TSVs 212A and TSVs 212B penetrate through the semiconductor substrate 211A and semiconductor substrate 211B, respectively. However, this disclosure is not limited thereto. In other embodiments, at this stage, the top surfaces of the TSVs 212A and TSVs 212B remain covered by the semiconductor substrate 211A and semiconductor substrate 211B, respectively. The top surfaces of the TSVs 212A and TSVs 212B will be exposed in a later process through the thinning of the semiconductor substrate 211A and semiconductor substrate 211B.

Referring to FIG. 1D, an insulating encapsulation 230 is formed to encapsulate the TIVs 220 and the interconnect dies 210A, 210B. In some embodiments, the insulating encapsulation 230 is initially formed to cover the top surfaces of the TIVs 220 and the interconnect dies 210A, 210B. A subsequent grinding process is then performed to thin the insulating encapsulation 230, thereby exposing the TIVs 220 and the interconnect dies 210A, 210B. In some embodiments, the TIVs 220 and the interconnect dies 210A, 210B may also be thinned during the grinding process. In some embodiments, the insulating encapsulation 230 is made of epoxy resins, phenolic resins, silicon-containing resins, or other suitable materials. The insulating encapsulation laterally surrounding the interconnect die and the at least one through insulating via

Referring to FIG. 1E, a routing structure 240 is formed over the insulating encapsulation 230 and electrically connected to the TIVs 220 and the interconnect dies 210A, 210B. In some embodiments, the routing structure 240 may also be referred to as an RDL structure and includes a dielectric structure 246, one or more RDLs 244, and vias 242. The dielectric structure 246 may include one or more dielectric layers, which may be made from materials such as silicon oxide, silicon nitride, silicon oxynitride, silicon carbide, or combinations thereof. Although two RDLs 244 are illustrated, the routing structure 240 may include more than two layers of RDLs 244. The RDLs 244 and the vias 242 may be formed using single- and/or dual-damascene processes, which involve etching the dielectric layers to form via openings and trenches, depositing a conductive barrier layer into the openings, plating a metallic material such as copper or a copper alloy, and performing planarization to remove excess metallic material. Additionally, etch stop layers may be present within the dielectric structure 246, though they are not explicitly shown in the figure.

In this embodiment, an interposer 200A includes the TIVs 220, the interconnect dies 210A, 210B, the insulating encapsulation 230, and the routing structure 240, all formed above the glass layer 100 and the first RDL structure 110. In some embodiments, the interposer 200A may be a reconstructed wafer; however, this disclosure is not limited thereto.

In some embodiments, the overall coefficient of thermal expansion (CTE) of the interposer 200A is approximately 3-10 ppm/°C (e.g., 5-6 ppm/°C). In certain embodiments, the overall CTE of the interposer 200A falls between the CTE of silicon (e.g., the silicon of the interconnect dies 210A and 210B, approximately 3 ppm/°C) and the CTE of the insulating encapsulation 230 (approximately 10 ppm/°C), depending on their relative proportions.

In some embodiments, the thickness T2 of the insulating encapsulation 230 ranges from 50 μm to 500 μm, such as 150 μm. However, other thicknesses of the insulating encapsulation 230 are also within the scope of the present disclosure. As shown in FIG. 1E, the thickness T1 of the glass layer 100 is smaller than the thickness T2 of the insulating encapsulation 230. However, the present disclosure is not limited thereto. In other embodiments, the thickness T1 of the glass layer 100 may be greater than or equal to the thickness T2 of the insulating encapsulation 230.

Referring to FIG. 1F, semiconductor devices 310, 320 are proved over the interposer 200A. Each semiconductor device 310, 320 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), a photonic integrated circuit (PIC), the like, or combinations thereof. The semiconductor devices 310, 320 may be a stacked device that includes multiple semiconductor substrates (not shown). For example, the semiconductor devices 310, 320 may be a memory device that includes multiple memory dies such as a hybrid memory cube (HMC) device, a high bandwidth memory (HBM) device, or the like. In some embodiments, each semiconductor device 310, 320 may be a single die or a package containing chiplets.

In some embodiments, the CTE of the semiconductor devices 310 and 320 is approximately 2-5 ppm/°C. For example, the material of the semiconductor devices 310 and 320 includes silicon, and the CTE of the semiconductor devices 310 and 320 is approximately 3 ppm/°C.

The semiconductor devices 310 and 320 are electrically connected to the interposer 200A. For example, in the present embodiment, the semiconductor devices 310 and 320 are respectively bonded to the routing structure 240 of the interposer 200A through connection terminals 312, 322. The connection terminals 312, 322 may include ball grid array (BGA) connectors, solder balls, metal pillars, controlled collapse chip connection (C4) bumps, micro bumps, bumps formed using the electroless nickel-electroless palladium-immersion gold (ENEPIG) technique, or the like. In other embodiments, the semiconductor devices 310 and 320 may also be bonded to the routing structure 240 of the interposer 200A using hybrid bonding or other bonding techniques.

An encapsulant 330 is formed over the semiconductor devices 310 and 320, as well as the routing structure 240. The encapsulant 330 covers the semiconductor devices 310 and 320 and fills the gaps between them. In some embodiments, the encapsulant 330 may be a molding compound, epoxy, or the like. The encapsulant 330 may or may not include fillers. It may be applied using compression molding, transfer molding, or similar techniques.

In the present embodiment, the encapsulant 330 encapsulates the connection terminals 312, 322. However, the present disclosure is not limited thereto. In other embodiments, additional underfill materials may be formed between the semiconductor devices 310 and 320 and the routing structure 240 to encapsulates the connection terminals 312, 322.

In some embodiments, the encapsulant 330 is initially applied to cover the top surfaces of the semiconductor devices 310 and 320. Then, through a planarization process (such as chemical mechanical polishing (CMP)), the top surfaces of the semiconductor devices 310 and 320 are exposed, and the top surfaces of the semiconductor devices 310 and 320 are substantially aligned with the top surface of the encapsulant 330.

In some embodiments, the thickness T3 of each of the semiconductor devices 310 and 320 ranges from 100 μm to 5000 μm, such as 700 μm. However, other thicknesses of the semiconductor devices 310 and 320 are also within the scope of the present disclosure.

Referring to FIGS. 1F and 1G, the glass layer 100, the interposer 200A, the semiconductor devices 310 and 320, and the encapsulant 330 are transferred from the first carrier C1 to a second carrier C2. For example, the workpiece on the first carrier C1 is first transferred onto the second carrier C2, allowing the semiconductor devices 310 and 320 and the encapsulant 330 to adhere to the second carrier C2. Subsequently, the first carrier C1 is separated from the glass layer 100 through the release film 101, thereby removing the first carrier C1 from the glass layer 100.

Although not explicitly shown in the figures, an adhesive layer, release film, or similar material may be provided between the second carrier C2 and the semiconductor devices 310 and 320, as well as the encapsulant 330.

Referring to FIG. 1H, through-glass vias (TGVs) 102 are formed in the glass layer 100 and electrically connected to the interposer 200A. In some embodiments, the TGVs 102 are formed through the following process: First, a laser modification process is performed on a portion of the glass layer 100 from the first surface 100a to alter the etching rate of the portion of the glass layer 100. Next, an etching process (such as wet etching) is used to remove the modified portions of the glass layer 100, thereby forming through-holes that expose the routing structure 240. A conductive material is then filled into the through-holes of the glass layer 100 to form the TGVs 102, which establish electrical connections to the routing structure 240. The TGVs 102 are formed from the first surface 100a of the glass layer 100.

In some embodiments, the materials used for the TGVs 102 include copper (Cu), gold (Au), nickel (Ni), silver (Ag), tin (Sn), electroless nickel/immersion gold (ENIG), or other metals.

Referring to FIG. 1I, optionally, a second RDL structure 120 is formed on the first surface 100a of the glass layer 100. In some embodiments, the second RDL structure 120 comprises a dielectric structure 126, one or more RDLs 124, and vias 122. The dielectric structure 126 may include one or more dielectric layers, which can be made from materials such as silicon oxide, silicon nitride, silicon oxynitride, silicon carbide, or combinations thereof. Although two RDLs 124 are illustrated, the second RDL structure 120 may include more than two layers of RDLs 124. The RDLs 124 and the vias 122 may be formed using single- and/or dual-damascene processes. These processes involve etching the dielectric layers to create via openings and trenches, depositing a conductive barrier layer into the openings, plating a metallic material such as copper or a copper alloy, and performing planarization to remove excess metallic material. Additionally, etch stop layers may be present within the dielectric structure 126, though they are not explicitly shown in the figure.

Referring to FIG. 1J, first connection structures 150 are formed on the second RDL structure 120. In this embodiment, the first connection structures 150 are formed on the second RDL structure 120 and are electrically connected to the TGVs 102 through the second RDL structure 120. However, the disclosure is not limited thereto. In other embodiments, the second RDL structure 120 may be omitted, and the first connection structures 150 may be formed directly on the TGVs 102. In some embodiments, the first connection structures 150 may be C4 bumps or other suitable connection structures.

In some embodiments, before or after forming the first connection structures 150, a singulation process is performed on the workpiece over the second carrier C2 to obtain the package component 10A. In some embodiments, after the singulation process, a sidewall 100S of the glass layer 100 is aligned with a sidewall 116S of the dielectric layer 116 and a sidewall 126S of the dielectric layer 126.

Referring to FIGS. 1J and 1K, the second carrier C2 is removed. The substrate 400A is electrically connected to the TGVs 102. The glass layer 100 is disposed between the substrate 400A and the interposer 200A. The first connection structures 150 and the second RDL structure 120 are disposed between the glass layer 100 and the substrate 400A. For example, the substrate 400A is bonded to the second RDL structure 120 through the first connection structures 150, allowing the substrate 400A to be electrically connected to the interposer 200A through the first connection structures 150, the second RDL structure 120, the TGVs 102, and the first RDL structure 110.

In some embodiments, the substrate 400A may include an organic core, a glass core, or a multilayer core, but the disclosure is not limited to these. The substrate 400A may also be coreless in structure. Additionally, the substrate 400A may optionally include core-embedded components (such as passive devices such as a multilayer ceramic chip (MLCC) capacitor die, an integrated passive device (IPD) die, an integrated voltage regulator (IVR) die, the like, or a combination thereof).

In some embodiments, the CTE of the substrate 400A is greater than the CTE of the interposer 200A. For example, the CTE of the substrate 400A is approximately 11-14 ppm/°C. In some embodiments, the substrate 400A includes an Ajinomoto buildup film (ABF), which has a CTE approximately between 11-14 ppm/°C. In some embodiments, the CTE of the glass layer 100 is greater than or equal to the CTE of the interposer 200A and smaller than the CTE of the substrate 400A.

In some embodiments, the thickness of the substrate 400A ranges from 1 mm to 10 mm, such as approximately 2 mm. However, the substrate 400A may also have other thicknesses.

A first underfill layer UF1 is formed between the package component 10A and the substrate 400A. The first underfill layer UF1 surrounds the first connection structures 150. In some embodiments, the first underfill layer UF1 is an electrically insulated adhesive for protecting the first connection structures 150. In some embodiments, the first underfill layer UF1 is made of epoxy, resin, epoxy molding compounds, another suitable underfill material, and/or a combination thereof.

In some embodiments, optionally, a ring structure 510 is provided and bonded to the substrate 400A. The bottom surface of the ring structure 510 is adhered to the illustrated top surface of the substrate 400A using an adhesive (not shown), with the ring structure 510 surrounding the package component 10A. Next, optionally, a lid 520 is provided and mounted onto the ring structure 510. For example, the bottom surface of the lid 520 is adhered to the top surface of the ring structure 510 using an adhesive (not shown). In some embodiments, a thermal interface material (not shown) is present between the lid 520 and the package component 10A.

Second connection structures 402 are formed on the bottom surface of the substrate 400A. The second connection structures 402 may include ball grid array (BGA) connectors, solder balls, metal pillars, controlled collapse chip connection (C4) bumps, or other similar structures. At this stage, the package structure 1 is substantially completed. The package structure 1 features a chip-on-wafer-on-substrate (CoWoS) structure, with the second connection structures 402 enabling electrical connection to an external device, such as an external printed circuit board (PCB) EB. In some embodiments, the external PCB EB has a CTE in the range of 16-18 ppm/°C and a thickness of several millimeters to several tens of millimeters.

In some embodiments, the glass layer 100 helps mitigate warpage issues in the structure. Generally, to prevent warpage-induced defects such as cracks and/or delamination in certain regions (e.g., in the underfill layer), the ratio of the area of the substrate 400A to the area of the package component 10A is typically set to be greater than 2. However, in the embodiments of the present disclosure, the inclusion of the glass layer 100 effectively addresses warpage concerns, thereby enlarging the process window. As a result, the ratio of the area of the substrate 400A to the area of the package component 10A is not limited to being greater than 2 but may also be less than or equal to 2. Additionally, the area of the package component 10A on the substrate 400A may be increased, meaning that more chips can be integrated within the package component 10A. Consequently, this enhances technology extensibility for larger packages and enables more chip integration.

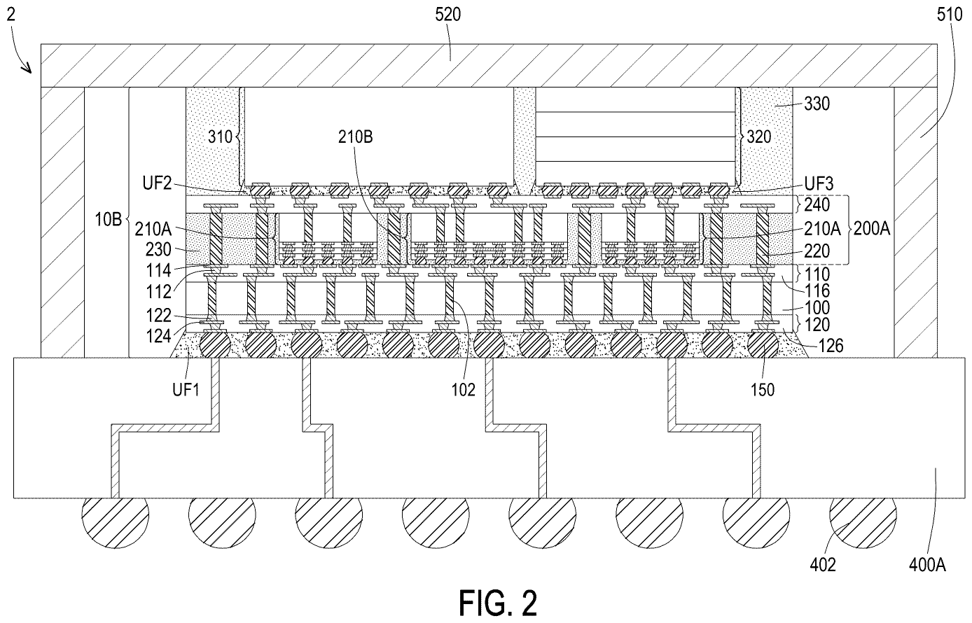

FIG. 2 is a schematic cross-sectional view showing a package structure 2 according to some embodiments of the present disclosure. The package structure 2 in FIG. 2 is similar to the package structure 1 in FIG. 1K, with the difference being that, in package structure 2, the package component 10B further includes a second underfill layer UF2 and the third underfill layer UF3. The second underfill layer UF2 is disposed between the semiconductor device 310 and the interposer 200A. The third underfill layer UF3 is disposed between the semiconductor device 320 and the interposer 200A.

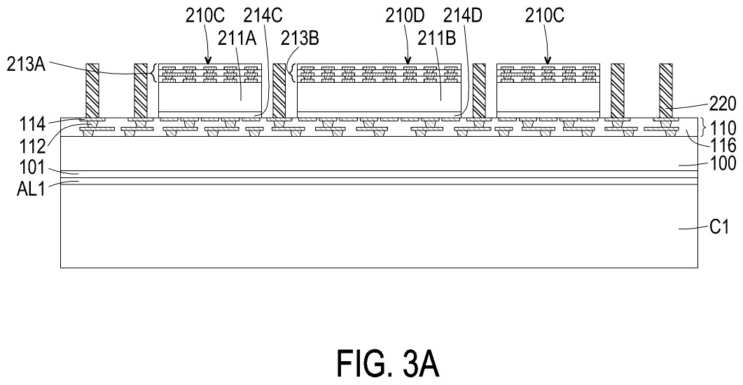

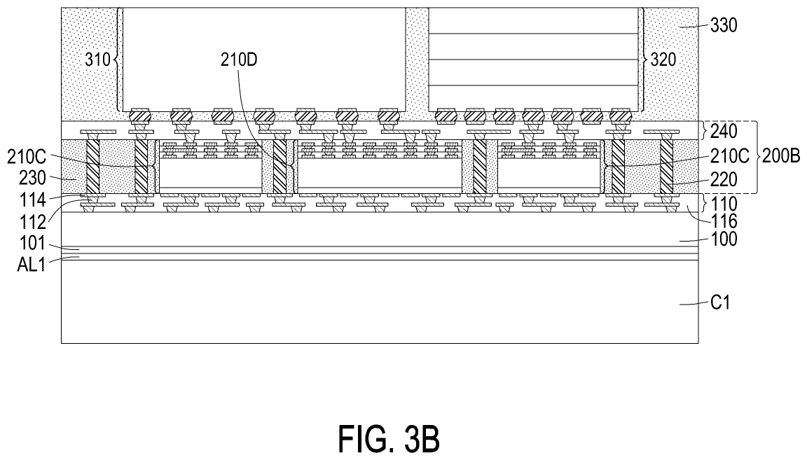

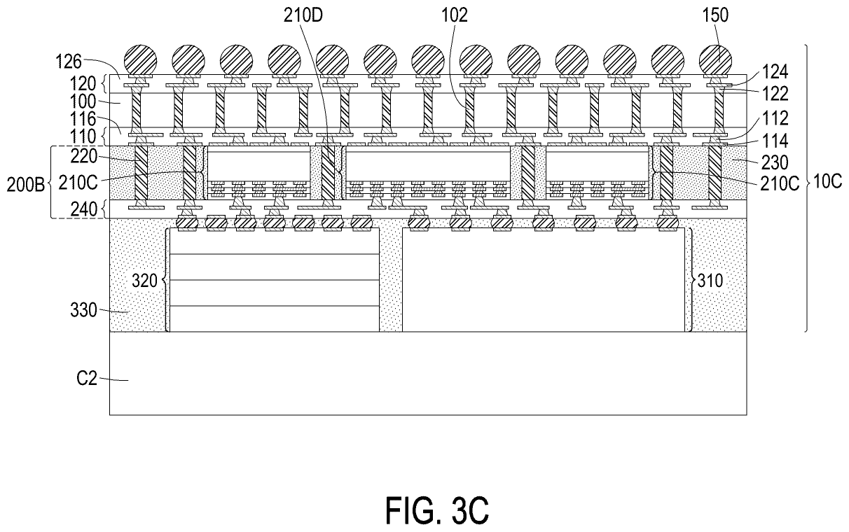

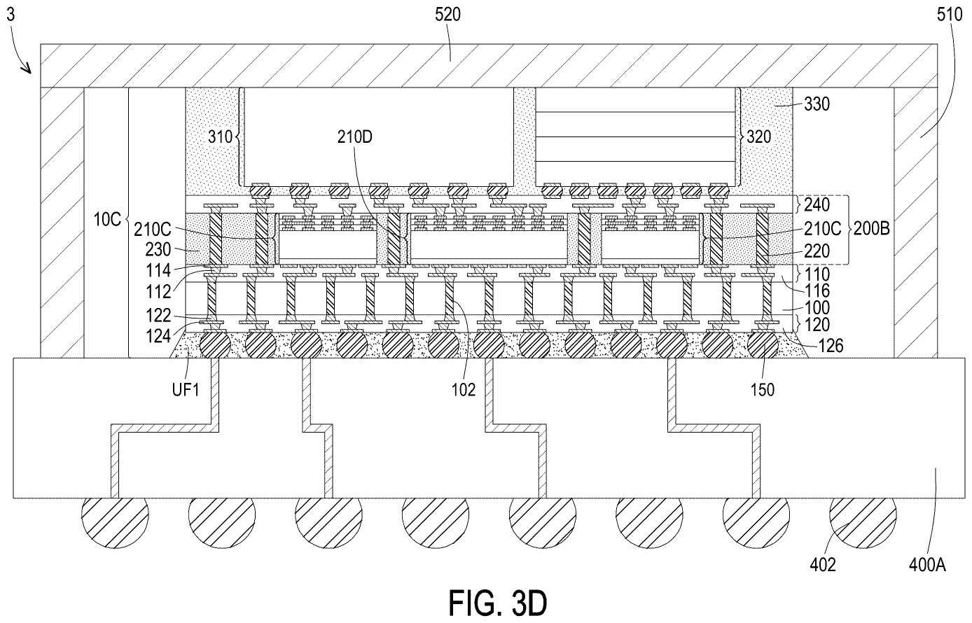

FIGS. 3A to 3D are schematic cross-sectional views showing various stages of a fabrication method for a package structure 3 according to some embodiments of the present disclosure. The embodiments in FIGS. 3A to 3D incorporate elements from the embodiments described in FIGS. 1A to 1K, and redundant details are omitted for brevity. Referring to FIG. 3A, the interconnect dies 210C and 210D are positioned on the first RDL structure 110. The interconnect dies 210C and 210D are attached to the top surface of the first RDL structure 110 using die attach films 214C and 214D, respectively. Additionally, in this embodiment, the interconnect structure 213A of interconnect die 210C and the interconnect structure 213B of interconnect die 210D are located on the sides of the semiconductor substrates 211A and 211B that face away from the first RDL structure 110.

Referring to FIG. 3B, an insulating encapsulation 230 is formed to encapsulate the TIVs 220 and the interconnect dies 210C, 210D. a routing structure 240 is formed over the insulating encapsulation 230 and electrically connected to the TIVs 220 and the interconnect dies 210A, 210B. Semiconductor devices 310, 320 are proved over the interposer 200B. An encapsulant 330 is formed over the semiconductor devices 310 and 320, as well as the routing structure 240.

Referring to FIG. 3C, the structure is transferred from the first carrier C1 to the second carrier C2, followed by the formation of the first connection structures 150 on the second RDL structure 120. In some embodiments, a singulation process is performed on the structure on the second carrier C2 either before or after forming the first connection structures 150 to obtain the package component 10C.

Finally, referring to FIG. 3D, the second carrier C2 is removed. The substrate 400A is electrically connected to the TGVs 102 and is bonded to the second RDL structure 120 through the first connection structures 150. The ring structure 510 is adhered to the illustrated top surface of the substrate 400A, with the ring structure 510 surrounding the package component 10C. A lid 520 is provided and mounted onto the ring structure 510.

The package structure 3 features a chip-on-wafer-on-substrate (CoWoS) structure, with the second connection structures 402 enabling electrical connection to an external device.

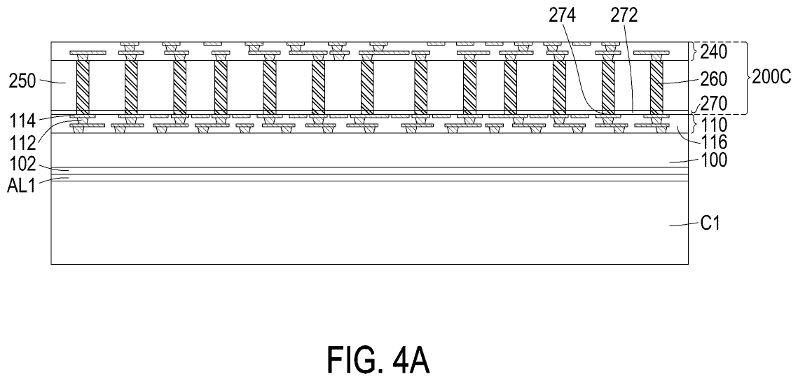

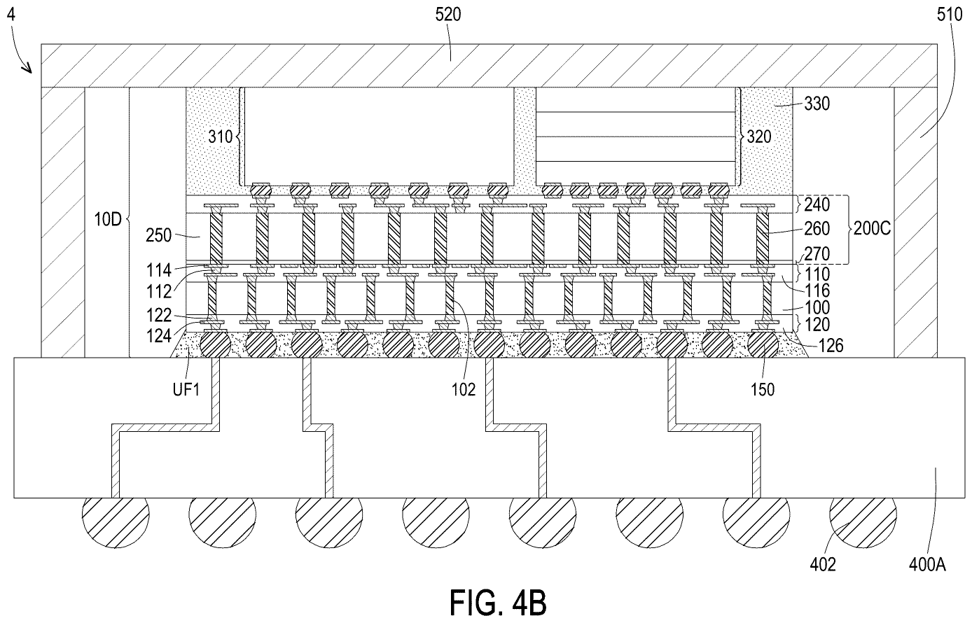

FIGS. 4A to 4B are schematic cross-sectional views showing various stages of a fabrication method for a package structure 4 according to some embodiments of the present disclosure. The embodiments in FIGS. 4A to 4B incorporate elements from the embodiments described in FIGS. 1A to 1K, and redundant details are omitted for brevity. Referring to FIG. 4A, in this embodiment, the first RDL structure 110 is first formed on the glass layer 100, followed by the formation of an interposer 200C on the first RDL structure 110. For example, the interposer 200C is bonded to the first RDL structure 110 using hybrid bonding or other suitable processes. In this embodiment, the interposer 200B includes a bonding layer 270, a substrate 250, through substrate vias 260, and a routing structure 240. The bonding layer 270 comprises a dielectric layer 272 and metal pads 274, which facilitate alignment and electrical connection with the first RDL structure 110. The substrate 250 is made of silicon or other semiconductor material. The through substrate vias 260 pass through the substrate 250, electrically connecting the metal pads 274 to the routing structure 240.

In some embodiments, the overall coefficient of thermal expansion (CTE) of the interposer 200C is approximately 3-5 ppm/°C. Since a significant portion of the interposer 200C consists of the substrate 250, the CTE of the interposer 200C is close to that of the substrate 250. For example, the CTE of the silicon of the substrate 250 is approximately 3 ppm/°C.

Referring to FIG. 4B, semiconductor devices 310, 320 are proved over the interposer 200C. An encapsulant 330 is formed over the semiconductor devices 310 and 320, as well as the routing structure 240.

The structure is transferred from the first carrier to the second carrier, followed by the formation of the TGVs 102, the second RDL structure 120, and the first connection structures 150. In some embodiments, a singulation process is performed on the structure on the second carrier either before or after forming the first connection structures 150 to obtain the package component 10D.

The second carrier is than removed. The substrate 400A is electrically connected to the TGVs 102 and is bonded to the second RDL structure 120 through the first connection structures 150. In some embodiments, the CTE of the substrate 400A is greater than the CTE of the interposer 200C. In some embodiments, the CTE of the glass layer 100 is greater than or equal to the CTE of the interposer 200C and smaller than the CTE of the substrate 400A.

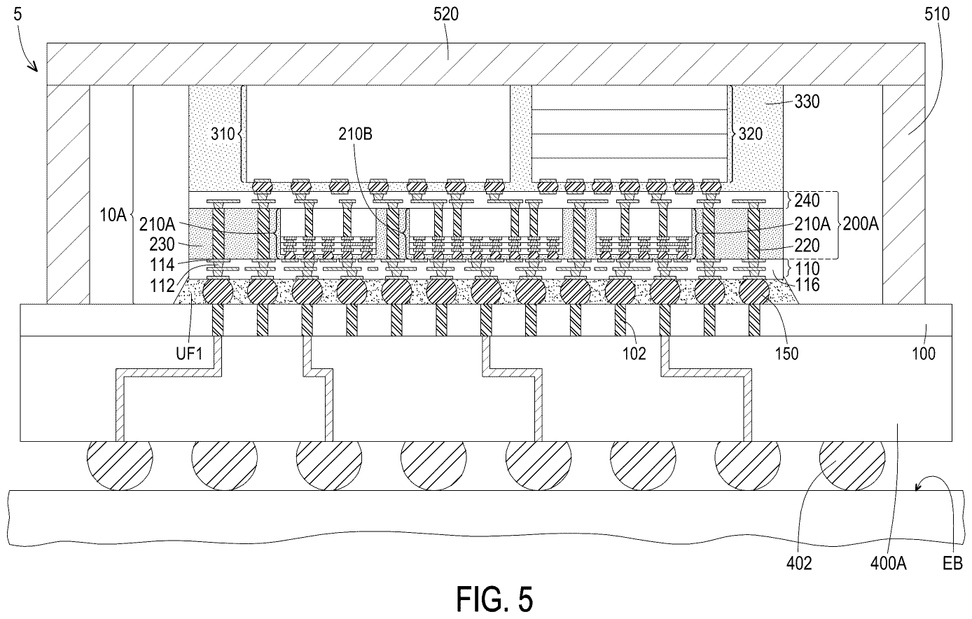

FIG. 5 is a schematic cross-sectional view showing a package structure 5 according to some embodiments of the present disclosure. The embodiments in FIG. 5 incorporate elements from the embodiments described in FIGS. 1A to 1K, and redundant details are omitted for brevity. The difference between the package structure 5 in FIG. 5 and the package structure 1 in FIG. 1K is that in the package structure 5, the glass layer 100 and the TGVs 102 are first formed over the substrate 400A, followed by the placement of the package component 10E over the glass layer 100. The package component 10E is electrically connected to the TGVs 102 through the first connection structures 150.

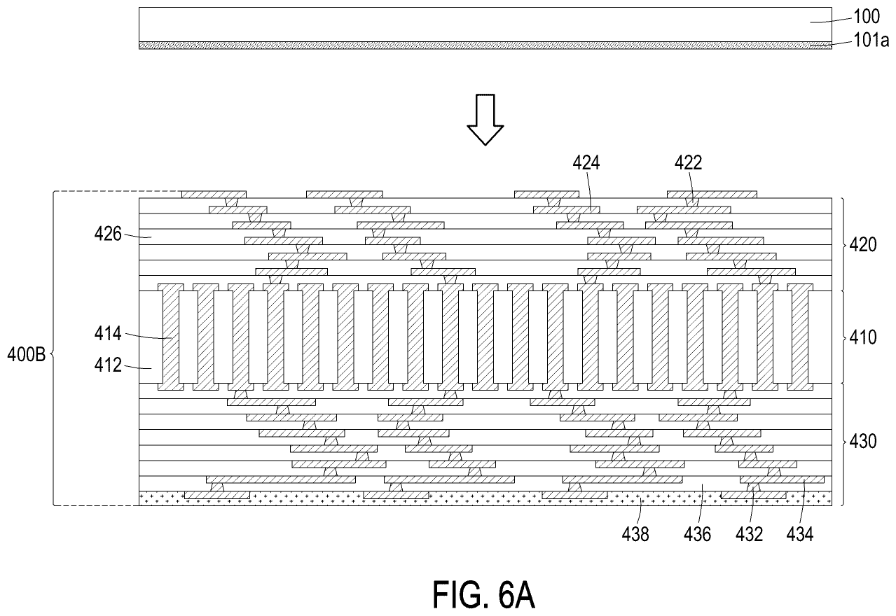

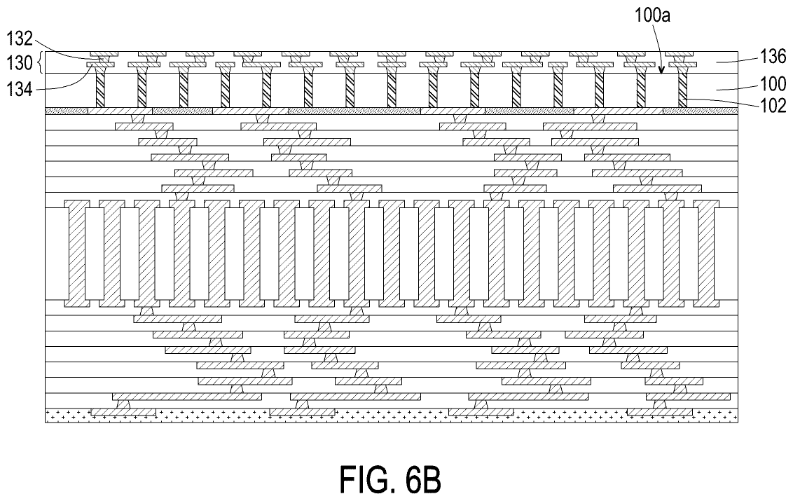

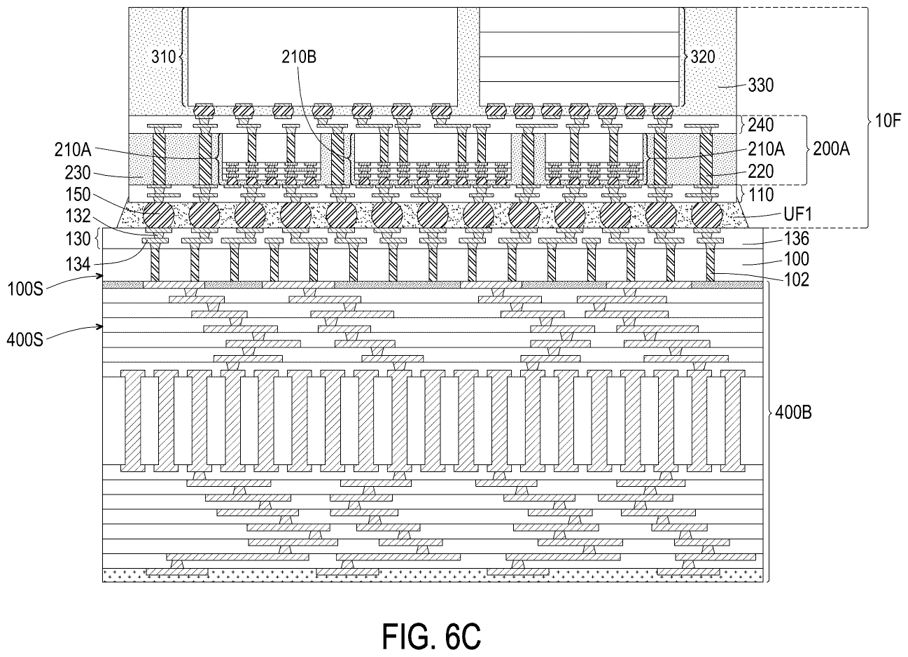

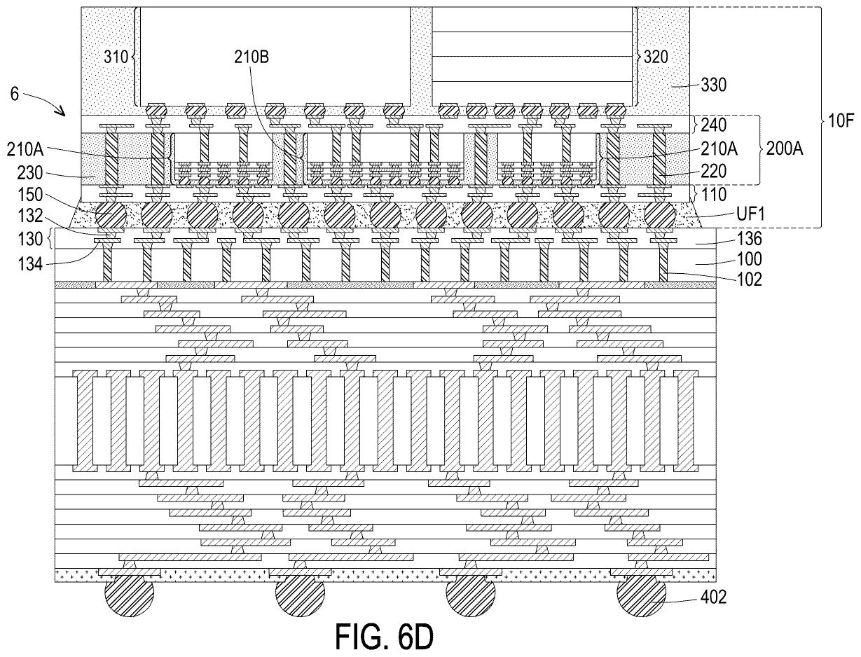

FIGS. 6A to 6D are schematic cross-sectional views showing various stages of a fabrication method for a package structure 6 according to some embodiments of the present disclosure. The embodiments in FIGS. 6A to 6D incorporate elements from the embodiments described in FIGS. 1A to 1K, and redundant details are omitted for brevity. Referring to FIG. 6A, a substrate 400B is provided. The substrate 400B includes a substrate core 410, a first ABF 420, and a second ABF 430.

The substrate core 410 includes a base 412 and conductive vias 414 that pass through the base 412. The base 412 may be made of glass, organic materials, or other suitable materials. The first ABF 420 and the second ABF 430 are respectively disposed on both sides of the substrate core 410, with the conductive via 414 electrically connecting the first ABF 420 and the second ABF 430.

In some embodiments, the first ABF 420 comprises multiple insulating layers 426, with conductive layers 424 and vias 422 distributed within the insulating layers 426. Similarly, the second ABF 430 comprises multiple insulating layers 436, with conductive layers 434 and vias 432 distributed within the insulating layers 436. In some embodiments, a solder resist layer 438 is formed on the surface of the second ABF 430, which faces away from the substrate core 410.

The glass layer 100 is bonded onto the substrate 400B. For example, the glass layer 100 is attached to the substrate 400B using an adhesive layer 101a. The adhesive layer 101a is attached to the substrate 400B and the glass layer 100.

In some embodiments, the CTE of the substrate 400B is between 11-14 ppm/°C. In some embodiments, the CTE of the glass layer 100 is smaller than the CTE of the substrate 400B.

Referring to FIG. 6B, TGVs 102 are formed in the glass layer 100 and electrically connected to the substrate 400B. In some embodiments, the TGVs 102 are formed through the following process: First, a laser modification process is performed on a portion of the glass layer 100 from the first surface 100a to alter the etching rate of the portion of the glass layer 100. Next, an etching process (such as wet etching) is used to remove the modified portions of the glass layer 100, thereby forming through-holes that expose the substrate 400B. A conductive material is then filled into the through-holes of the glass layer 100 to form the TGVs 102, which establish electrical connections to the substrate 400B. The TGVs 102 are formed from the first surface 100a of the glass layer 100.

In some embodiments, the materials used for the TGVs 102 include copper (Cu), gold (Au), nickel (Ni), silver (Ag), tin (Sn), electroless nickel/immersion gold (ENIG), or other metals.

Referring to FIG. 6B, a RDL structure 130 is formed over the glass layer 100 and the TGVs 102. In some embodiments, the RDL structure 130 comprises a dielectric structure 136, one or more RDLs 134, and vias 132. The dielectric structure 136 may include one or more dielectric layers, which may be made from materials such as silicon oxide, silicon nitride, silicon oxynitride, silicon carbide, or combinations thereof. Although two RDLs 134 are illustrated, the RDL structure 130 may include more than two layers of RDLs 134. The RDLs 134 and the vias 132 may be formed using single- and/or dual-damascene processes, which involve etching the dielectric layers to form via openings and trenches, depositing a conductive barrier layer into the openings, plating a metallic material such as copper or a copper alloy, and performing planarization to remove excess metallic material. Additionally, etch stop layers may be present within the dielectric structure 136, though they are not explicitly shown in the figure.

Referring to FIG. 6C, a package component 10D is provided. The package component 10F includes the first RDL structure 110, the interposer 200A, semiconductor devices 310 and 320, the encapsulant 330, and first connection structures 150. The package component 10F is bonded onto the RDL structure 130 through the first connection structures 150. The first connection structures 150 are disposed over the RDL structure 130 and between the glass layer 100 and the interposer 200A. The first connection structures 150 are electrically connected to the TGVs 102 and the interposer 200A. The first underfill layer UF1 is surrounding the first connection structures 150.

In some embodiments, a sidewall 100S of the glass layer 100 is aligned with a sidewall 400S of the substrate 400B.

Referring to FIG. 6D, second connection structures 402 are formed on the bottom surface of the substrate 400B. The second connection structures 402 may include ball grid array (BGA) connectors, solder balls, metal pillars, controlled collapse chip connection (C4) bumps, or other similar structures.

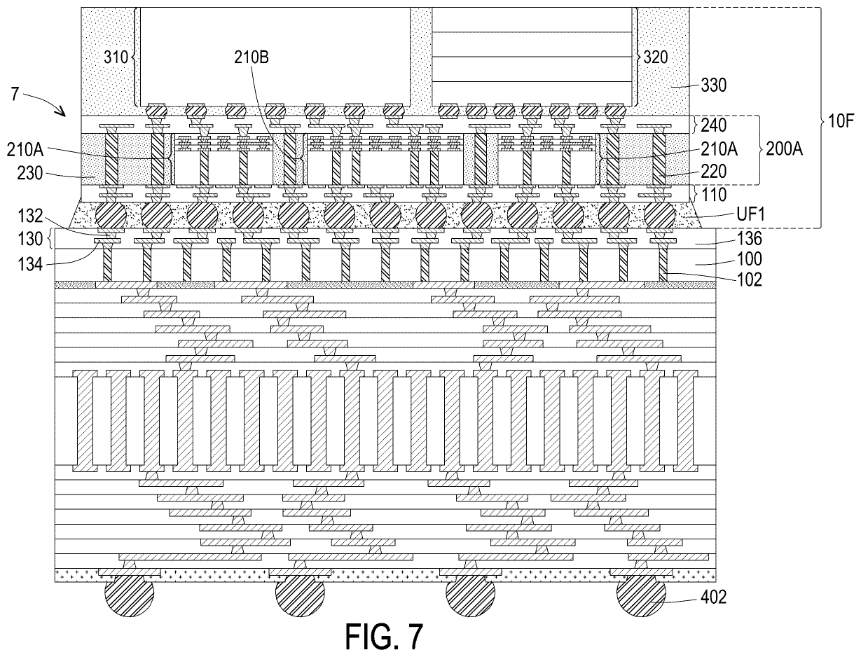

FIG. 7 is a schematic cross-sectional view showing a package structure 7 according to some embodiments of the present disclosure. The package structure 7 in FIG. 7 is similar to the package structure 6 in FIG. 6D, with the difference being that in the package structure 7, the active sides of the interconnect dies 210A and 210B in the interposer 200A face the semiconductor devices 310 and 320. In contrast, in the package structure 6, the active sides of the interconnect dies 210A and 210B in the interposer 200A face the glass layer 100.

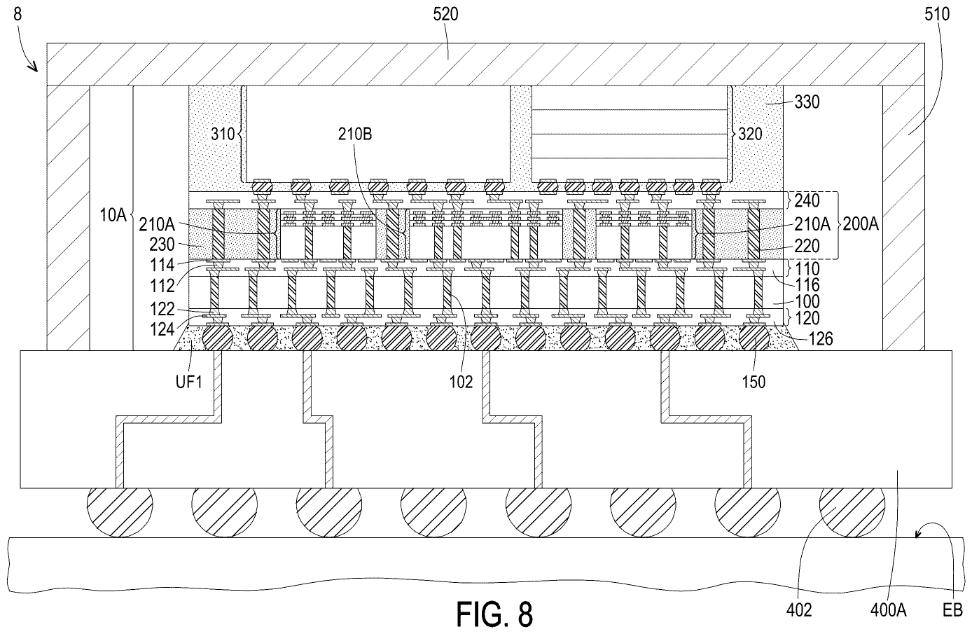

FIG. 8 is a schematic cross-sectional view showing a package structure 8 according to some embodiments of the present disclosure. The package structure 8 in FIG. 8 is similar to the package structure 1 in FIG. 1K, with the difference being that in the package structure 8, the active sides of the interconnect dies 210A and 210B in the interposer 200A face the semiconductor devices 310 and 320. In contrast, in the package structure 1, the active sides of the interconnect dies 210A and 210B in the interposer 200A face the glass layer 100.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In some embodiments of the present disclosure, a package structure is provided. The package structure includes a substrate, an interposer, a glass layer, through glass vias (TGVs), and a semiconductor device. The interposer is disposed over the substrate. The glass layer is disposed between the substrate and the interposer. The TGVs are embedded in the glass layer and electrically connected to the substrate and the interposer. The semiconductor device is disposed over and electrically connected to the interposer.

In some embodiments of the present disclosure, a fabrication method of a package structure includes the following steps: forming an interposer over a glass layer; providing a semiconductor device over the interposer, wherein the semiconductor device is electrically connected to the interposer; forming a plurality of through glass vias in the glass layer, wherein the plurality of through glass vias are electrically connected to the interposer; and electrically connecting a substrate to the plurality of through glass vias, wherein the glass layer is disposed between the substrate and the interposer.

In some embodiments of the present disclosure, a fabrication method of a package structure includes the following steps: bonding a glass layer onto a substrate; forming a plurality of through glass vias in the glass layer, wherein the plurality of through glass vias are electrically connected to the substrate; and bonding a package component onto the glass layer, wherein the package component comprises an interposer and a semiconductor device disposed over and electrically connected to the interposer, wherein the glass layer is disposed between the substrate and the interposer, and the plurality of through glass vias are electrically connected to the interposer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a substrate;
an interposer, disposed over the substrate;
a glass layer, disposed between the substrate and the interposer;
a plurality of conductive vias in the glass layer; and
a semiconductor device, disposed over and electrically connected to the interposer.

2. The package structure of claim 1, further comprising:
a first redistribution layer structure, disposed between the glass layer and the interposer.

3. The package structure of claim 2, wherein the first redistribution layer structure comprises at least one redistribution layer in a dielectric layer, and a sidewall of the glass layer is aligned with a sidewall of the dielectric layer.

4. The package structure of claim 1, further comprising:
a second redistribution layer structure, disposed between the glass layer and the substrate.

5. The package structure of claim 4, wherein the second redistribution layer structure comprises at least one redistribution layer in a dielectric layer, and a sidewall of the glass layer is aligned with a sidewall of the dielectric layer.

6. The package structure of claim 1, further comprising:
a plurality of first connection structures, disposed between the glass layer and the substrate, wherein the plurality of first connection structures are electrically connected to the plurality of conductive vias ; and
a first underfill layer, surrounding the plurality of first connection structures.

7. The package structure of claim 1, further comprising:
an adhesive layer formed between the substrate and the glass layer;
a redistribution layer structure, disposed over the glass layer;
a plurality of first connection structures, disposed over the redistribution layer structure and between the glass layer and the interposer, wherein the plurality of first connection structures are electrically connected to the plurality of conductive vias and the interposer; and
a first underfill layer, surrounding the plurality of first connection structures.

8. The package structure of claim 1, wherein a sidewall of the glass layer is aligned with a sidewall of the substrate.

9. The package structure of claim 1, wherein a coefficient of thermal expansion of the glass layer is in a range from 3 ppm/°C to 12 ppm/°C.

10. The package structure of claim 1, wherein a coefficient of thermal expansion of the glass layer is greater than a coefficient of thermal expansion of the interposer and smaller than a coefficient of thermal expansion of the substrate.

11. The package structure of claim 1, wherein the interposer comprises:
an interconnect die, disposed over the glass layer, wherein the interconnect die comprises:
a semiconductor substrate;
at least one through semiconductor via, embedded in the semiconductor substrate;
at least one through insulating via, disposed over the glass layer; and
an insulating encapsulation, disposed over the glass layer and laterally surrounding the interconnect die and the at least one through insulating via; and
a routing structure, disposed over the insulating encapsulation and electrically connected to the at least one through insulating via and the interconnect die.

12. The package structure of claim 1, wherein a thickness of the glass layer is in a range from 0.1 mm to 1 mm.

13. The package structure of claim 1, wherein the glass layer comprises a glass material doped with at least one of sodium oxide and potassium oxide.

14. A fabrication method of a package structure, comprising:
forming an interposer over a glass layer;
providing a semiconductor device over the interposer, wherein the semiconductor device is electrically connected to the interposer;
forming a plurality of through glass vias in the glass layer, wherein the plurality of through glass vias are electrically connected to the interposer; and
electrically connecting a substrate to the plurality of through glass vias, wherein the glass layer is disposed between the substrate and the interposer.

15. The fabrication method of claim 14, further comprising:
bonding the glass layer onto a first carrier before forming the interposer over the glass layer, wherein a first surface of the glass layer is facing to the first carrier;
transferring the glass layer, the interposer, and the semiconductor device from the first carrier to a second carrier;
removing the first carrier from the glass layer;
forming the plurality of through glass vias from the first surface of the glass layer; and
removing the second carrier.

16. The fabrication method of claim 14, further comprising:
forming a first redistribution layer structure on the glass layer; and
forming the interposer over the first redistribution layer structure.

17. The fabrication method of claim 14, further comprising:
forming a second redistribution layer structure on the glass layer;
forming a plurality of first connection structures on the second redistribution layer structure;
bonding the substrate to the second redistribution layer structure through the plurality of first connection structures; and
forming a first underfill layer surrounding the plurality of first connection structures.

18. A fabrication method of a package structure, comprising:
bonding a glass layer onto a substrate;
forming a plurality of through glass vias in the glass layer, wherein the plurality of through glass vias are electrically connected to the substrate; and
bonding a package component onto the glass layer, wherein the package component comprises an interposer and a semiconductor device disposed over and electrically connected to the interposer, wherein the glass layer is disposed between the substrate and the interposer, and the plurality of through glass vias are electrically connected to the interposer.

19. The fabrication method of claim 18, wherein the glass layer is bonded to the substrate through an adhesive layer.

20. The fabrication method of claim 18, further comprising:
forming a redistribution layer structure over the plurality of through glass vias;
bonding the package component onto the glass layer through a plurality of first connection structures; and
forming a first underfill layer surrounding the plurality of first connection structures.
